(19) United States
(12) Patent Application Publication
(10) Pub. No.: US 2025/0077734 A1
(43) Pub. Date: Mar. 6, 2025

(54) INTEGRATED ASSET MODELING FOR ENERGY CONSUMPTION AND EMISSION

(71) Applicant: Schlumberger Technology Corporation, Sugar Land, TX (US)

(72) Inventors: David Rowan, Abingdon (GB); Syed Abdul Samad Ali, Abingdon (GB); Stephen Freeman, London (GB)

(21) Appl. No.: 18/724,939

(22) PCT Filed: Feb. 9, 2023
(86) PCT No.: PCT/US2023/062303

§ 371 Date: Jun. 27, 2024

Related U.S. Application Data
(60) Provisional application No. 63/267,753, filed on Feb. 9, 2022.

(51) Int. Cl. G06F 30/20; G01V 20/00; G06F 30/13

(52) U.S. Cl. CPC G06F 30/20; G01V 20/00; G06F 30/13

(57) ABSTRACT

A method for quantifying and managing energy consumption and emissions equivalents of a subsurface development plan includes generating a plurality of digital representations of the subsurface development plan. The subsurface development plan includes a plurality of wellbores. The method also includes determining fluid production rates from the wellbores, fluid injection rates into the wellbores, or both based upon the digital representations. The method also includes determining that the fluid production rates, the fluid injection rates, or both are within operational constraints, achieve predetermined objectives, or both. The method also includes determining the energy consumption and the emissions equivalents based upon the digital representations. The emissions equivalents correspond to the energy consumption. The method also includes generating a plurality of different subsurface development plans based upon the energy consumption, the emissions equivalents, or both.

### CROSS-REFERENCE TO RELATED APPLICATIONS

This patent application claims priority to U.S. Provisional Patent Application No. 63/267,753, filed on Feb. 9, 2022, the entirety of which is incorporated by reference.

### BACKGROUND

Subsurface development operations use large amounts of energy during construction and operations. For example, large amounts of energy may be used to run pumps, compress fluids, inject fluids, and run separation and processing facilities. This energy may be expensive to generate. In addition, the consumption of this energy may lead to direct emissions of greenhouse gases (GHG).

### SUMMARY

Embodiments of the present disclosure may provide a method for quantifying and managing energy consumption and emissions equivalents of a subsurface development plan includes generating a plurality of digital representations of the subsurface development plan. The subsurface development plan includes a plurality of wellbores. The method also includes determining fluid production rates from the wellbores, fluid injection rates into the wellbores, or both based upon the digital representations. The method also includes determining that the fluid production rates, the fluid injection rates, or both are within operational constraints, achieve predetermined objectives, or both. The method also includes determining the energy consumption and the emissions equivalents based upon the digital representations. The emissions equivalents correspond to the energy consumption. The method also includes generating a plurality of different subsurface development plans based upon the energy consumption, the emissions equivalents, or both.

Embodiments may also include a computing system. The computing system includes one or more processors and a memory system. The memory system includes one or more non-transitory computer-readable media storing instructions that, when executed by at least one of the one or more processors, cause the computing system to perform operations. The operations include generating a plurality of digital representations of a subsurface development plan. The digital representations include construction, maintenance, or interventions for wellbores, pipelines, equipment, or a combination thereof. The digital representations are used to predict oil and gas production, underground gas storage, carbon sequestration, or a combination thereof. Each digital representation includes a reservoir simulation model of a subsurface, a model of a wellsite infrastructure, and a model of a surface infrastructure. The operations also include determining fluid production rates from the wellbores based upon the digital representations. The operations also include determining fluid injection rates into the wellbores based upon the digital representations. The operations also include determining that the fluid production rates and the fluid injection rates are within operational constraints of the wellbores, the pipelines, the equipment, or a combination thereof. The operations also include determining that the fluid production rates and the fluid injection rates achieve predetermined objectives. The operations also include determining greenhouse gas (GHG) emissions from the surface infrastructure. The operations also include determining energy consumption based upon the digital representations. The energy consumption is determined in response to determining that the fluid injection rates and the fluid production rates are within the operational constraints and achieve the predetermined objectives. The operations also include determining emissions equivalents corresponding to the energy consumption based upon the digital representations. The operations also include generating a plurality of different subsurface development plans based upon the GHG emissions, the energy consumption, the emissions equivalents, or a combination thereof.

Embodiments may also include a non-transitory computer-readable medium storing instructions that, when executed by at least one processor of a computing system, cause the computing system to perform operation. The operations include generating a plurality of digital representations of a subsurface development plan. The digital representations include construction, maintenance, and interventions for wellbores, pipelines, equipment, or a combination thereof. The digital representations are used to predict oil and gas production, underground gas storage, carbon sequestration, or a combination thereof. Each digital representation includes a reservoir simulation model of a subsurface. The reservoir simulation model includes a description of an architecture of the subsurface, reservoir compartmentalization, rock and fluid properties, fluid flow characteristics, geometries of the wellbores, or a combination thereof. The reservoir simulation model incorporates an impact of subsurface uncertainty in geological structure and rock and fluid property distributions. Each digital representation also includes a model of a wellsite infrastructure. The wellsite infrastructure includes the wellbores, the pipelines, the equipment, or a combination thereof. Each digital representation also includes a model of a surface infrastructure. The surface infrastructure includes an oil and gas processing facility, a carbon capture and compression facility, or both. The operations also include determining fluid production rates from the wellbores based upon the digital representations. The operations also include determining fluid injection rates into the wellbores based upon the digital representations. The operations also include determining that the fluid production rates and the fluid injection rates are within operational constraints of the wellbores, pipelines, and equipment. The operational constraints include minimum and maximum flow rates, minimum and maximum pressures, minimum and maximum temperatures, availability of resources to perform the construction, maintenance, and interventions, or a combination thereof. The operations also include determining that the fluid production rates and the fluid injection rates achieve predetermined objectives. The predetermined objectives include oil production rates, gas production rates, gas injection rates, water production rates, water injection rates, or a combination thereof. The operations also include determining greenhouse gas (GHG) emissions from the surface infrastructure based upon the digital representations. The operations also include determining energy consumption based upon the digital representations. The energy consumption is determined in response to determining that the fluid injection rates and the fluid production rates are within the operational constraints and achieve the predetermined objectives. The energy consumption includes energy consumption to construct the wellbores, energy consumption to operate the wellbores, energy consumption to provide fluid lifting in the wellbores, energy consumption to process and transport the produced and injected fluids, or a combination thereof. The operations also include determining emissions equivalents corresponding to the energy consumption based upon the digital representations. The emissions equivalents are different from the GHG emissions and include emissions that are created when producing the energy consumed in the digital representations. The operations also include generating a plurality of different subsurface development plans based upon the GHG emissions, the energy consumption, the emissions equivalents, or a combination thereof. Each of the different subsurface development plans includes a multi-year plan for designing and building the wellsite infrastructure and the surface infrastructure. Each of the different development plan implements different fluid injection rates and different fluid production rates to produce different GHG emissions, different energy consumption, and different emissions equivalents.

This summary is provided to introduce a selection of concepts that are further described below in the detailed description. This summary is not intended to identify key or essential features of the claimed subject matter, nor is it intended to be used as an aid in limiting the scope of the claimed subject matter.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIGS. 1A, 1B, 1C, 1D, 2, 3A, and 3B illustrate simplified, schematic views of an oilfield and its operation, according to an embodiment.

FIGS. 4A-4C illustrate a flowchart of a method for evaluating different scenarios to modify (e.g., optimize) production with reduced emissions, according to an embodiment.

FIG. 5 illustrates a schematic view of an automated subsurface ensemble generation, according to an embodiment.

FIG. 6 illustrates a perspective view of a connected oilfield production system with surface and subsurface components, according to an embodiment.

FIG. 7 illustrates a schematic view of a field management strategy, according to an embodiment.

FIG. 8 illustrates a schematic view of energy consumption models, according to an embodiment.

FIGS. 9A and 9B illustrate a multi-fidelity model workflow for fluid production rates calculation, according to an embodiment.

FIGS. 10A-10I illustrate a plurality of graphs that show how different development options may be evaluated to compare production alongside energy consumption metrics, according to an embodiment.

FIGS. 11A-11I illustrate a plurality of graphs that show the cumulative energy consumption from different sources for different field development scenarios, according to an embodiment.

+

FIG. 12A illustrates a graph showing total energy consumption (e.g., 3-yearly totals), and FIG. 12B illustrates a graph showing oil production cumulative for the base and modified (e.g., optimal) field development plan, according to an embodiment.

FIG. 13 illustrates a graph showing a comparison of cumulative energy consumption and CO₂ equivalent emissions, according to an embodiment.

FIG. 14 illustrates a flowchart of a method for quantifying and managing energy consumption and emissions equivalents of a subsurface development plan, according to an embodiment.

FIG. 15 illustrates a computing system for performing at least a portion of the method(s) disclosed herein, according to an embodiment.

### DETAILED DESCRIPTION

Reference will now be made in detail to embodiments, examples of which are illustrated in the accompanying drawings and figures. In the following detailed description, numerous specific details are set forth in order to provide a thorough understanding of the invention. However, it will be apparent to one of ordinary skill in the art that the invention may be practiced without these specific details. In other instances, well-known methods, procedures, components, circuits and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object could be termed a second object, and, similarly, a second object could be termed a first object, without departing from the scope of the invention. The first object and the second object are both objects, respectively, but they are not to be considered the same object.

The terminology used in the description of the invention herein is for the purpose of describing particular embodiments only and is not intended to be limiting of the invention. As used in the description of the invention and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

Attention is now directed to processing procedures, methods, techniques and workflows that are in accordance with some embodiments. Some operations in the processing procedures, methods, techniques and workflows disclosed herein may be combined and/or the order of some operations may be changed.

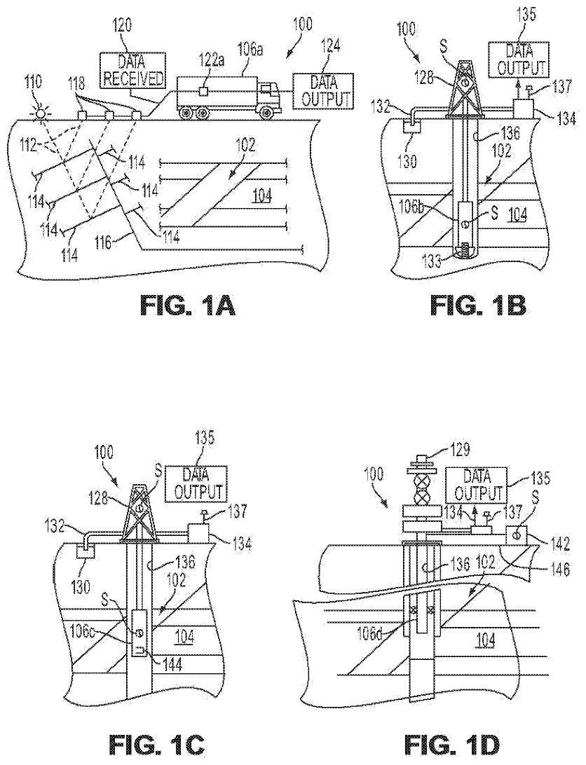

FIGS. 1A-1D illustrate simplified, schematic views of oilfield 100 having subterranean formation 102 containing reservoir 104 therein in accordance with implementations of various technologies and techniques described herein. FIG. 1A illustrates a survey operation being performed by a survey tool, such as seismic truck 106.1, to measure properties of the subterranean formation. The survey operation is a seismic survey operation for producing sound vibrations. In FIG. 1A, one such sound vibration, e.g., sound vibration 112 generated by source 110, reflects off horizons 114 in earth formation 116. A set of sound vibrations is received by sensors, such as geophone-receivers 118, situated on the earth's surface. The data received 120 is provided as input data to a computer 122.1 of a seismic truck 106.1, and responsive to the input data, computer 122.1 generates seismic data output 124. This seismic data output may be stored, transmitted or further processed as desired, for example, by data reduction.

FIG. 1B illustrates a drilling operation being performed by drilling tools 106.2 suspended by rig 128 and advanced into subterranean formations 102 to form wellbore 136. Mud pit 130 is used to draw drilling mud into the drilling tools via flow line 132 for circulating drilling mud down through the drilling tools, then up wellbore 136 and back to the surface. The drilling mud is typically filtered and returned to the mud pit. A circulating system may be used for storing, controlling, or filtering the flowing drilling mud. The drilling tools are advanced into subterranean formations 102 to reach reservoir 104. Each well may target one or more reservoirs. The drilling tools are adapted for measuring downhole properties using logging while drilling tools. The logging while drilling tools may also be adapted for taking core sample 133 as shown.

Computer facilities may be positioned at various locations about the oilfield 100 (e.g., the surface unit 134) and/or at remote locations. Surface unit 134 may be used to communicate with the drilling tools and/or offsite operations, as well as with other surface or downhole sensors. Surface unit 134 is capable of communicating with the drilling tools to send commands to the drilling tools, and to receive data therefrom. Surface unit 134 may also collect data generated during the drilling operation and produce data output 135, which may then be stored or transmitted.

Sensors(S), such as gauges, may be positioned about oilfield 100 to collect data relating to various oilfield operations as described previously. As shown, sensor(S) is positioned in one or more locations in the drilling tools and/or at rig 128 to measure drilling parameters, such as weight on bit, torque on bit, pressures, temperatures, flow rates, compositions, rotary speed, and/or other parameters of the field operation. Sensors(S) may also be positioned in one or more locations in the circulating system.

Drilling tools 106.2 may include a bottom hole assembly (BHA) (not shown), generally referenced, near the drill bit (e.g., within several drill collar lengths from the drill bit). The bottom hole assembly includes capabilities for measuring, processing, and storing information, as well as communicating with surface unit 134. The bottom hole assembly further includes drill collars for performing various other measurement functions.

The bottom hole assembly may include a communication subassembly that communicates with surface unit 134. The communication subassembly is adapted to send signals to and receive signals from the surface using a communications channel such as mud pulse telemetry, electro-magnetic telemetry, or wired drill pipe communications. The communication subassembly may include, for example, a transmitter that generates a signal, such as an acoustic or electromagnetic signal, which is representative of the measured drilling parameters. It will be appreciated by one of skill in the art that a variety of telemetry systems may be employed, such as wired drill pipe, electromagnetic or other known telemetry systems.

Typically, the wellbore is drilled according to a drilling plan that is established prior to drilling. The drilling plan typically sets forth equipment, pressures, trajectories and/or other parameters that define the drilling process for the wellsite. The drilling operation may then be performed according to the drilling plan. However, as information is gathered, the drilling operation may need to deviate from the drilling plan. Additionally, as drilling or other operations are performed, the subsurface conditions may change. The earth model may also need adjustment as new information is collected

The data gathered by sensors(S) may be collected by surface unit 134 and/or other data collection sources for analysis or other processing. The data collected by sensors(S) may be used alone or in combination with other data. The data may be collected in one or more databases and/or transmitted on or offsite. The data may be historical data, real time data, or combinations thereof. The real time data may be used in real time, or stored for later use. The data may also be combined with historical data or other inputs for further analysis. The data may be stored in separate databases, or combined into a single database.

Surface unit 134 may include transceiver 137 to allow communications between surface unit 134 and various portions of the oilfield 100 or other locations. Surface unit 134 may also be provided with or functionally connected to one or more controllers (not shown) for actuating mechanisms at oilfield 100. Surface unit 134 may then send command signals to oilfield 100 in response to data received. Surface unit 134 may receive commands via transceiver 137 or may itself execute commands to the controller. A processor may be provided to analyze the data (locally or remotely), make the decisions and/or actuate the controller. In this manner, oilfield 100 may be selectively adjusted based on the data collected. This technique may be used to optimize (or improve) portions of the field operation, such as controlling drilling, weight on bit, pump rates, or other parameters. These adjustments may be made automatically based on computer protocol, and/or manually by an operator. In some cases, well plans may be adjusted to select optimum (or improved) operating conditions, or to avoid problems.

FIG. 1C illustrates a wireline operation being performed by wireline tool 106.3 suspended by rig 128 and into wellbore 136 of FIG. 1B. Wireline tool 106.3 is adapted for deployment into wellbore 136 for generating well logs, performing downhole tests and/or collecting samples. Wireline tool 106.3 may be used to provide another method and apparatus for performing a seismic survey operation. Wireline tool 106.3 may, for example, have an explosive, radioactive, electrical, or acoustic energy source 144 that sends and/or receives electrical signals to surrounding subterranean formations 102 and fluids therein.

Wireline tool 106.3 may be operatively connected to, for example, geophones 118 and a computer 122.1 of a seismic truck 106.1 of FIG. 1A. Wireline tool 106.3 may also provide data to surface unit 134. Surface unit 134 may collect data generated during the wireline operation and may produce data output 135 that may be stored or transmitted. Wireline tool 106.3 may be positioned at various depths in the wellbore 136 to provide a survey or other information relating to the subterranean formation 102.

Sensors(S), such as gauges, may be positioned about oilfield 100 to collect data relating to various field operations as described previously. As shown, sensor S is positioned in wireline tool 106.3 to measure downhole parameters which relate to, for example porosity, permeability, fluid composition and/or other parameters of the field operation.

FIG. 1D illustrates a production operation being performed by production tool 106.4 deployed from a production unit or Christmas tree 129 and into completed wellbore 136 for drawing fluid from the downhole reservoirs into surface facilities 142. The fluid flows from reservoir 104 through perforations in the casing (not shown) and into production tool 106.4 in wellbore 136 and to surface facilities 142 via gathering network 146.

Sensors(S), such as gauges, may be positioned about oilfield 100 to collect data relating to various field operations as described previously. As shown, the sensor(S) may be positioned in production tool 106.4 or associated equipment, such as Christmas tree 129, gathering network 146, surface facility 142, and/or the production facility, to measure fluid parameters, such as fluid composition, flow rates, pressures, temperatures, and/or other parameters of the production operation.

Production may also include injection wells for added recovery. One or more gathering facilities may be operatively connected to one or more of the wellsites for selectively collecting downhole fluids from the wellsite(s).

While FIGS. 1B-1D illustrate tools used to measure properties of an oilfield, it will be appreciated that the tools may be used in connection with non-oilfield operations, such as gas fields, mines, aquifers, storage or other subterranean facilities. Also, while certain data acquisition tools are depicted, it will be appreciated that various measurement tools capable of sensing parameters, such as seismic two-way travel time, density, resistivity, production rate, etc., of the subterranean formation and/or its geological formations may be used. Various sensors(S) may be located at various positions along the wellbore and/or the monitoring tools to collect and/or monitor the desired data. Other sources of data may also be provided from offsite locations.

The field configurations of FIGS. 1A-1D are intended to provide a brief description of an example of a field usable with oilfield application frameworks. Part of, or the entirety, of oilfield 100 may be on land, water and/or sea. Also, while a single field measured at a single location is depicted, oilfield applications may be utilized with any combination of one or more oilfields, one or more processing facilities and one or more wellsites.

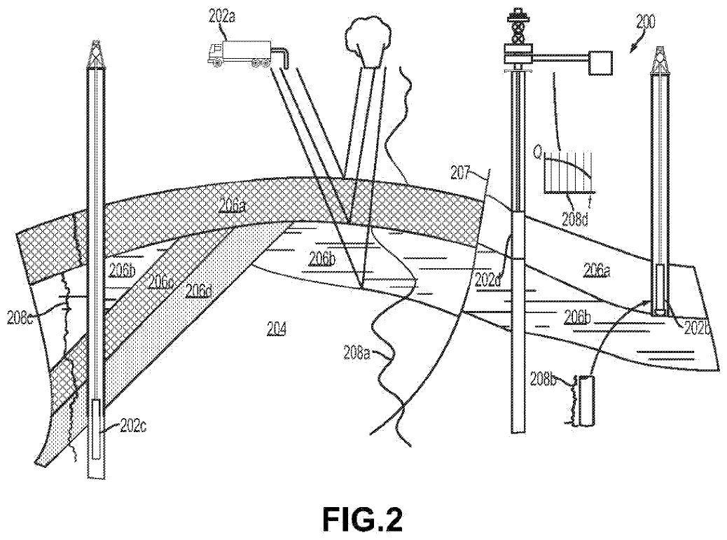

FIG. 2 illustrates a schematic view, partially in cross section of oilfield 200 having data acquisition tools 202.1, 202.2, 202.3 and 202.4 positioned at various locations along oilfield 200 for collecting data of subterranean formation 204 in accordance with implementations of various technologies and techniques described herein. Data acquisition tools 202.1-202.4 may be the same as data acquisition tools 106.1-106.4 of FIGS. 1A-1D, respectively, or others not depicted. As shown, data acquisition tools 202.1-202.4 generate data plots or measurements 208.1-208.4, respectively. These data plots are depicted along oilfield 200 to demonstrate the data generated by the various operations.

Data plots 208.1-208.3 are examples of static data plots that may be generated by data acquisition tools 202.1-202.3, respectively; however, it should be understood that data plots 208.1-208.3 may also be data plots that are updated in real time. These measurements may be analyzed to better define the properties of the formation(s) and/or determine the accuracy of the measurements and/or for checking for errors. The plots of each of the respective measurements may be aligned and scaled for comparison and verification of the properties.

Static data plot 208.1 is a seismic two-way response over a period of time. Static plot 208.2 is core sample data measured from a core sample of the formation 204. The core sample may be used to provide data, such as a graph of the density, porosity, permeability, or some other physical property of the core sample over the length of the core. Tests for density and viscosity may be performed on the fluids in the core at varying pressures and temperatures. Static data plot 208.3 is a logging trace that typically provides a resistivity or other measurement of the formation at various depths.

A production decline curve or graph 208.4 is a dynamic data plot of the fluid flow rate over time. The production decline curve typically provides the production rate as a function of time. As the fluid flows through the wellbore, measurements are taken of fluid properties, such as flow rates, pressures, composition, etc.

Other data may also be collected, such as historical data, user inputs, economic information, and/or other measurement data and other parameters of interest. As described below, the static and dynamic measurements may be analyzed and used to generate models of the subterranean formation to determine characteristics thereof. Similar measurements may also be used to measure changes in formation aspects over time.

The subterranean structure 204 has a plurality of geological formations 206.1-206.4. As shown, this structure has several formations or layers, including a shale layer 206.1, a carbonate layer 206.2, a shale layer 206.3 and a sand layer 206.4. A fault 207 extends through the shale layer 206.1 and the carbonate layer 206.2. The static data acquisition tools are adapted to take measurements and detect characteristics of the formations.

While a specific subterranean formation with specific geological structures is depicted, it will be appreciated that oilfield 200 may contain a variety of geological structures and/or formations, sometimes having extreme complexity. In some locations, typically below the water line, fluid may occupy pore spaces of the formations. Each of the measurement devices may be used to measure properties of the formations and/or its geological features. While each acquisition tool is shown as being in specific locations in oilfield 200, it will be appreciated that one or more types of measurement may be taken at one or more locations across one or more fields or other locations for comparison and/or analysis.

The data collected from various sources, such as the data acquisition tools of FIG. 2, may then be processed and/or evaluated. Typically, seismic data displayed in static data plot 208.1 from data acquisition tool 202.1 is used by a geophysicist to determine characteristics of the subterranean formations and features. The core data shown in static plot 208.2 and/or log data from well log 208.3 are typically used by a geologist to determine various characteristics of the subterranean formation. The production data from graph 208.4 is typically used by the reservoir engineer to determine fluid flow reservoir characteristics. The data analyzed by the geologist, geophysicist and the reservoir engineer may be analyzed using modeling techniques.

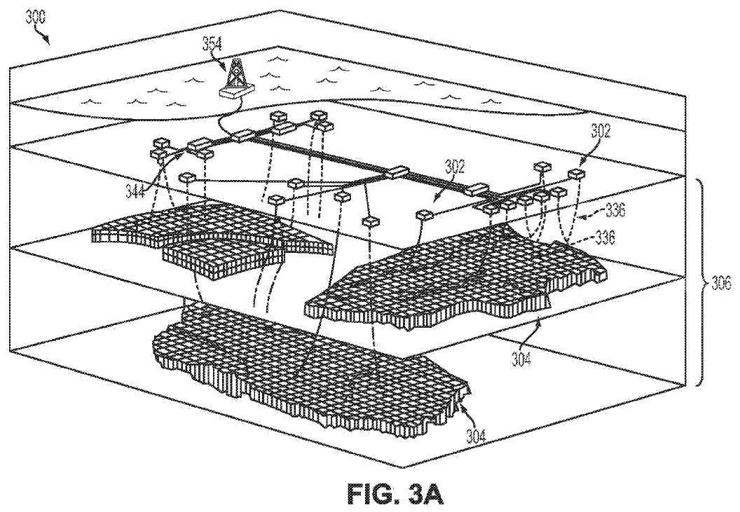

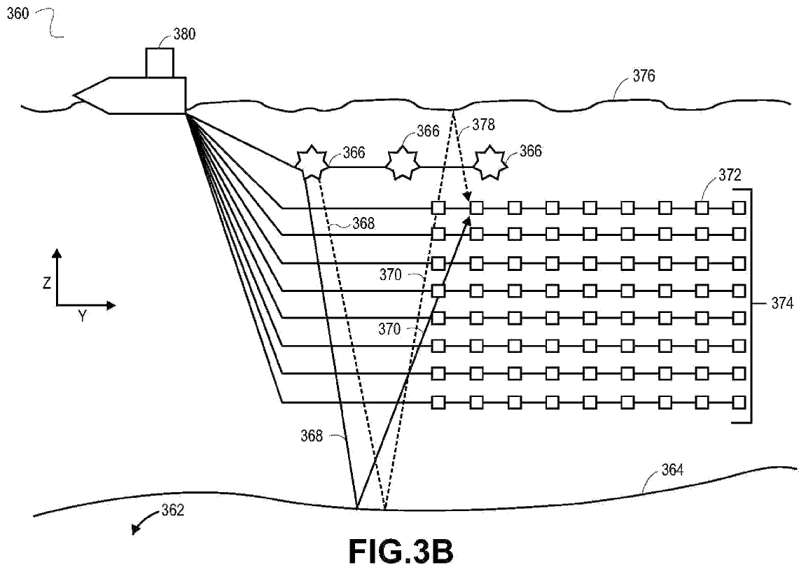

FIG. 3A illustrates an oilfield 300 for performing production operations in accordance with implementations of various technologies and techniques described herein. As shown, the oilfield has a plurality of wellsites 302 operatively connected to central processing facility 354. The oilfield configuration of FIG. 3A is not intended to limit the scope of the oilfield application system. Part, or all, of the oilfield may be on land and/or sea. Also, while a single oilfield with a single processing facility and a plurality of wellsites is depicted, any combination of one or more oilfields, one or more processing facilities and one or more wellsites may be present.

Each wellsite 302 has equipment that forms wellbore 336 into the earth. The wellbores extend through subterranean formations 306 including reservoirs 304. These reservoirs 304 contain fluids, such as hydrocarbons. The wellsites draw fluid from the reservoirs and pass them to the processing facilities via surface networks 344. The surface networks 344 have tubing and control mechanisms for controlling the flow of fluids from the wellsite to processing facility 354.

Attention is now directed to FIG. 3B, which illustrates a side view of a marine-based survey 360 of a subterranean subsurface 362 in accordance with one or more implementations of various techniques described herein. Subsurface 362 includes seafloor surface 364. Seismic sources 366 may include marine sources such as vibroseis or airguns, which may propagate seismic waves 368 (e.g., energy signals) into the Earth over an extended period of time or at a nearly instantaneous energy provided by impulsive sources. The seismic waves may be propagated by marine sources as a frequency sweep signal. For example, marine sources of the vibroseis type may initially emit a seismic wave at a low frequency (e.g., 5 Hz) and increase the seismic wave to a high frequency (e.g., 80-90 Hz) over time.

The component(s) of the seismic waves 368 may be reflected and converted by seafloor surface 364 (i.e., reflector), and seismic wave reflections 370 may be received by a plurality of seismic receivers 372. Seismic receivers 372 may be disposed on a plurality of streamers (i.e., streamer array 374). The seismic receivers 372 may generate electrical signals representative of the received seismic wave reflections 370. The electrical signals may be embedded with information regarding the subsurface 362 and captured as a record of seismic data.

In one implementation, each streamer may include streamer steering devices such as a bird, a deflector, a tail buoy and the like, which are not illustrated in this application. The streamer steering devices may be used to control the position of the streamers in accordance with the techniques described herein.

In one implementation, seismic wave reflections 370 may travel upward and reach the water/air interface at the water surface 376, a portion of reflections 370 may then reflect downward again (i.e., sea-surface ghost waves 378) and be received by the plurality of seismic receivers 372. The sea-surface ghost waves 378 may be referred to as surface multiples. The point on the water surface 376 at which the wave is reflected downward is generally referred to as the downward reflection point.

The electrical signals may be transmitted to a vessel 380 via transmission cables, wireless communication or the like. The vessel 380 may then transmit the electrical signals to a data processing center. Alternatively, the vessel 380 may include an onboard computer capable of processing the electrical signals (i.e., seismic data). Those skilled in the art having the benefit of this disclosure will appreciate that this illustration is highly idealized. For instance, surveys may be of formations deep beneath the surface. The formations may typically include multiple reflectors, some of which may include dipping events, and may generate multiple reflections (including wave conversion) for receipt by the seismic receivers 372. In one implementation, the seismic data may be processed to generate a seismic image of the subsurface 362. Marine seismic acquisition systems tow each streamer in streamer array 374 at the same depth (e.g., 5-10 m). However, marine based survey 360 may tow each streamer in streamer array 374 at different depths such that seismic data may be acquired and processed in a manner that avoids the effects of destructive interference due to sea-surface ghost waves. For instance, marine-based survey 360 of FIG. 3B illustrates eight streamers towed by vessel 380 at eight different depths. The depth of each streamer may be controlled and maintained using the birds disposed on each streamer.

Integrated Asset Modeling and Optimization for Energy Consumption and Emission

This present disclosure includes a system and method that model, in a consistent and integrated manner, how different subsurface development plans for oil and gas, and underground gas storage, including carbon capture and storage (CCS), can be evaluated against energy transition metrics. The system and method may also modify (e.g., optimize) the model and/or plans to improve decision making during the energy transition. The plans may be or include multi-year programs of well, pipeline, and facility construction and operation.

The system and method may forecast direct greenhouse gas (GHG) emissions (e.g., across the operation) and the energy consumption for any oilfield development across the lifetime of the operations. Different scenarios can be compared for the energy efficiency and carbon intensity of operations, and development plans can be constructed to hit economic and/or emission targets while ensuring a sustainable development plan.

The present disclosure includes a system which systematically quantifies energy consumption associated with oil and gas field operations in both (1) initial construction of wells, pipelines, and equipment and (2) operation of oilfield activity, including maintenance and oilfield interventions. The system may quantify greenhouse gas emissions from the oilfield infrastructure. The system may also quantify direct energy consumption and emission for fuel combustion to run oilfield operations. The system may also quantify CO₂ emission equivalent (CO₂e) of the energy consumption to provide direct calculation of emissions for oilfield options. The system may automatically direct energy to renewal or low-emission energy sources as they become available and modify (e.g., optimize) the scheduling of the transition. The system may evaluate different sourcing scenarios for energy consumption across oilfield development and operation and the impact of these scenarios on emissions and energy efficiency. The system may recommend modified (e.g., optimal) sustainable field development, which minimizes energy consumption and emissions, while maintaining operating targets and/or maximizing economic value of the asset. The system may incorporate the impact of subsurface uncertainty in geological structure and property distributions on the forecasted energy consumption and emissions.

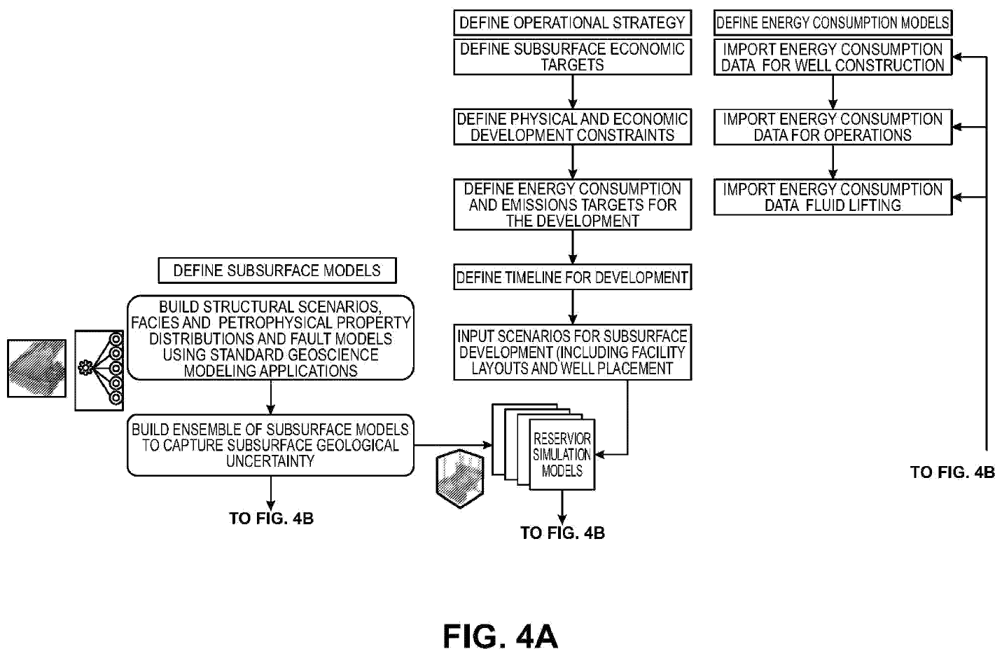

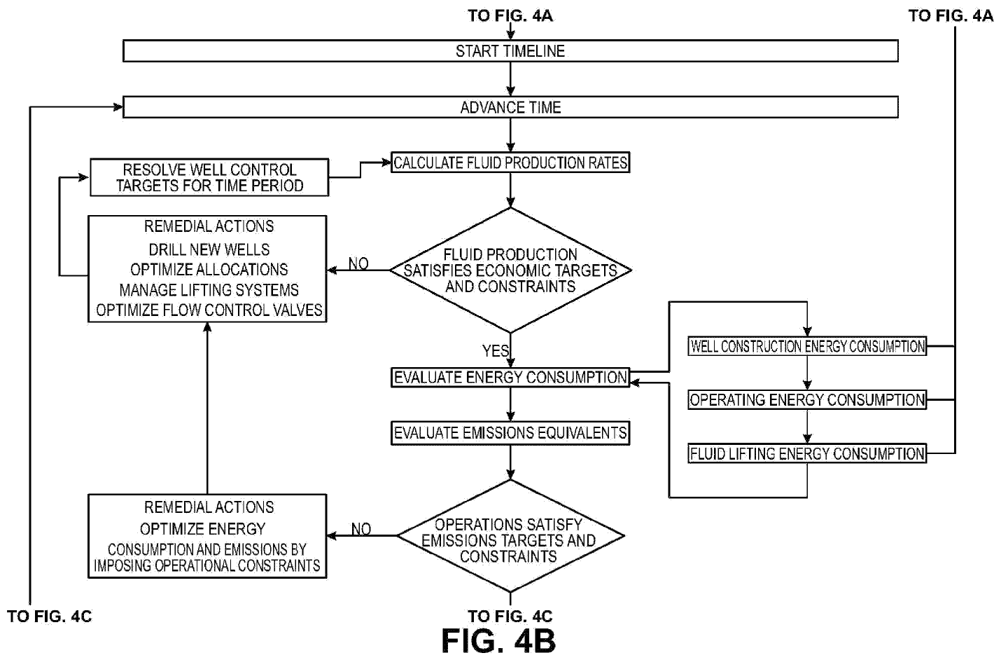

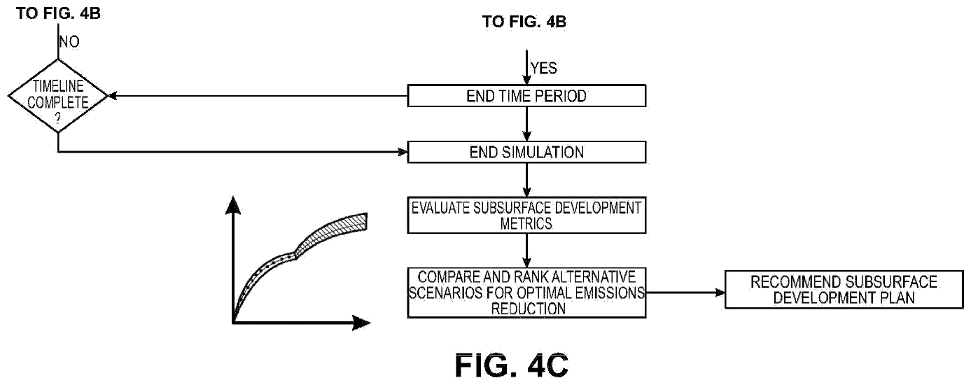

FIGS. 4A-4C illustrate a flowchart of a method for evaluating different scenarios to modify (e.g., optimize) subsurface production with reduced emissions, according to an embodiment. The method may include building an integrated subsurface and field development model, which includes one or more models of energy consumption for the relevant processes. More particularly, the method may include (1) defining and/or generating a subsurface model, (2) defining and/or generating a layout and operational strategy model (e.g., a field management model), and/or (3) defining and/or generating an energy consumption model. Once the model(s) has/have been generated, the model(s) may be advanced through time, and two additional processes may be performed at each time period: (4) evaluation and optimization of economics and emissions metrics, and (5) comparison and recommendation on development plan. The method may evaluate multiple different scenarios for modifying (e.g., optimizing) production with reduced emissions.

### Building the Integrated Field Development and Energy Consumption Model

### Generation of Subsurface Model Ensembles

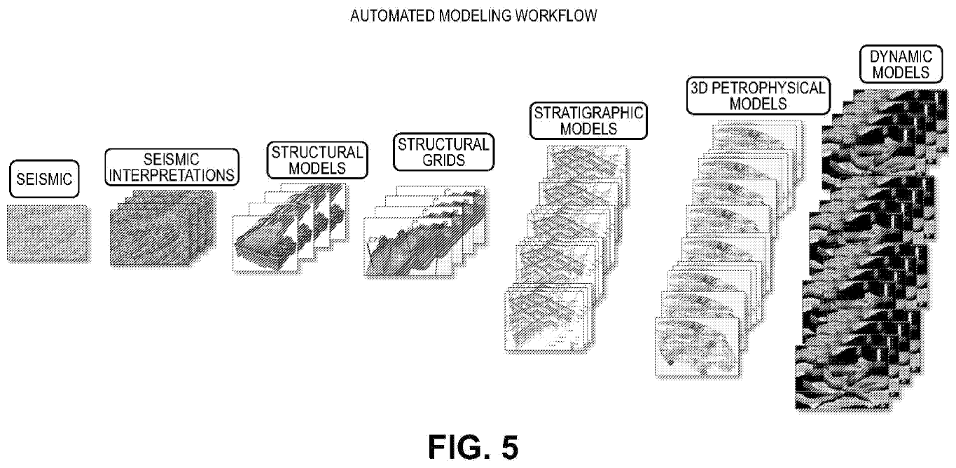

Subsurface interpretation and modeling workflows may be used to build reservoir models from available oilfield data including seismic survey data, well logs, core samples, and historical production data. This may be in an integrated geoscience and reservoir modeling environment. Given the sparsity of data acquisition, there may be uncertainty in the geological interpretation of the subsurface. As a result, ensemble modeling workflows may be used, which generate multiple realizations of equiprobable subsurface models, for use in decision-making workflows. The generation of these ensembles benefits from cloud HPC and automation as illustrated in FIG. 5. More particularly, FIG. 5 illustrates a schematic view of an automated subsurface ensemble generation, according to an embodiment. This may also or instead be referred to as agile reservoir modeling (ARM).

### Layout and Operational Strategy Model (Field Management Model)

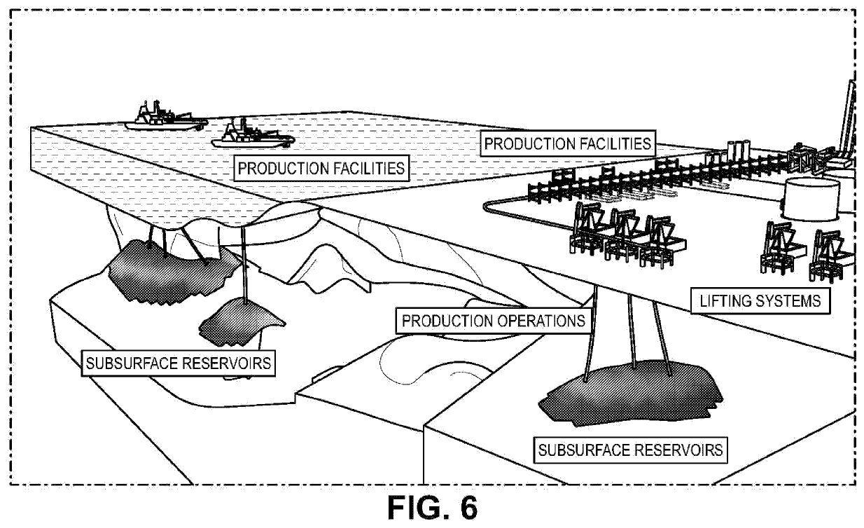

FIG. 6 illustrates a perspective view of a connected oilfield production system with surface and subsurface components, according to an embodiment. The layout of actual and proposed field development components may be defined. This may include well locations and architectures, completion design, and pipeline routing and connection to surface production/injection facilities.

A user may define the targets for the subsurface development. The targets may be consumption targets, production targets, emission targets, economic targets, or a combination thereof. For example, the targets may be hydrocarbon production targets over the duration of an oilfield lifetime, CO₂ storage injection targets for a CCS development, heat production for a geothermal development, or a combination thereof.

Physical operational flow constraints on the system may also be defined, alongside availability of resource constraints. For example, the rate at which new wells can be created due to drilling rig availability may be defined. At this stage, the energy consumption operational and emissions targets and operational constraints may be defined for the development.

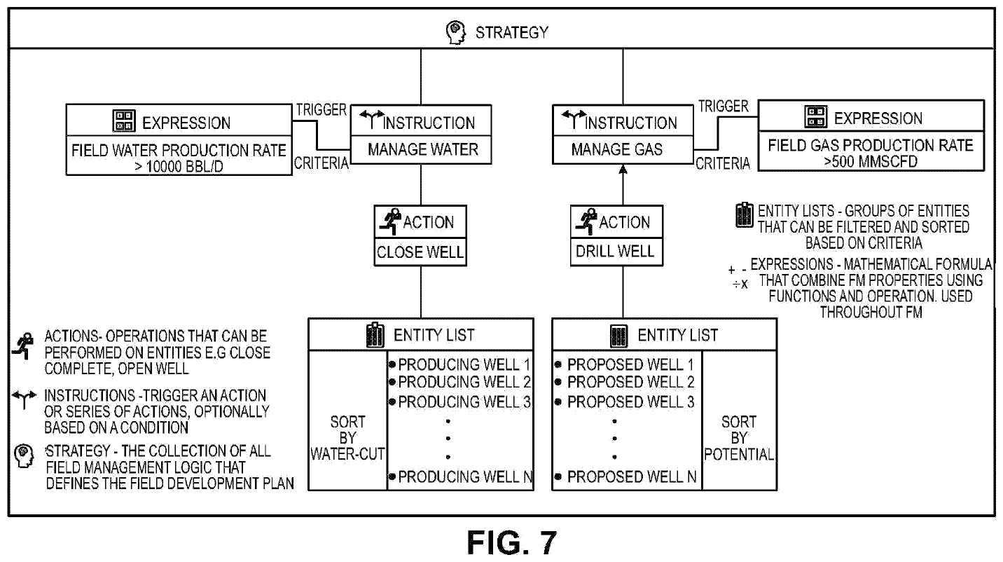

In addition, a timeline for the development and an operational strategy may be defined. The operational strategy may include two components: scheduled events and reactive events. The scheduled events may be or include a set of events such as opening new wells, drill start dates, and/or planned maintenance events, which happen at predefined dates in the timeline. The reactive events may be or include a set of rules that define what to do if certain criteria are met during the production operations. For example, a well may be instructed to close if the production falls below a certain threshold value. Another example is the drilling of a new well to enable new production to come online to meet a production target or contracted rate. The set of rules forms the asset development strategy. Each rule may be specified in the form of expressions (e.g., functional dependencies on observed triggering criteria), instructions (e.g., a list of control points and a set of actions to perform in a specified order), actions (e.g., set of operations to be performed on the oilfield control points), and/or entity list (e.g., combinations of oilfield control points where user intervention can be made). FIG. 7 illustrates a schematic view of a field management strategy, according to an embodiment.

### Energy Consumption Models

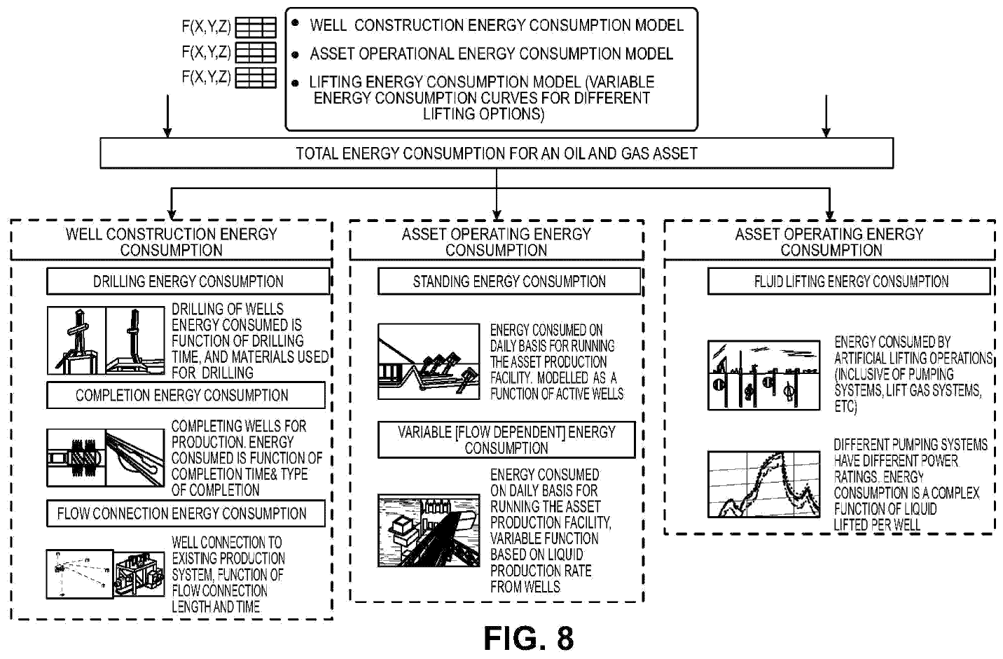

FIG. 8 illustrates a schematic view of energy consumption models, according to an embodiment. The energy consumption models may be defined and/or generated for the subsurface development. This may include well construction energy consumption (e.g., the energy used in drilling, completing, and/or connecting new wells which come online during the development), asset operational energy consumption (e.g., the energy to operate wells, flow lines, and/or production facilities), asset fluid lifting energy consumption (e.g., the energy to operate artificial lift systems and pumping systems), or a combination thereof. These may be entered as either tabular look-up data, functions/equations, or standalone models which can be used to calculate energy consumption during the evaluation of a multi-year development plan.

### Evaluation of Field Development Scenarios

When the model has been defined and/or generated, the system can be advanced through time to evaluate and modify (e.g., optimize) the objectives for the field development including the carbon intensity and emissions to deliver the proposed field development. A field management orchestration engine with inbuilt scheduler may drive the advancement of the field development evaluation through time. At each point in time, a calculation model may be used to calculate the production (or injection) of fluid to meet the operational targets and constraints.

### Calculation of Fluid Production Rates

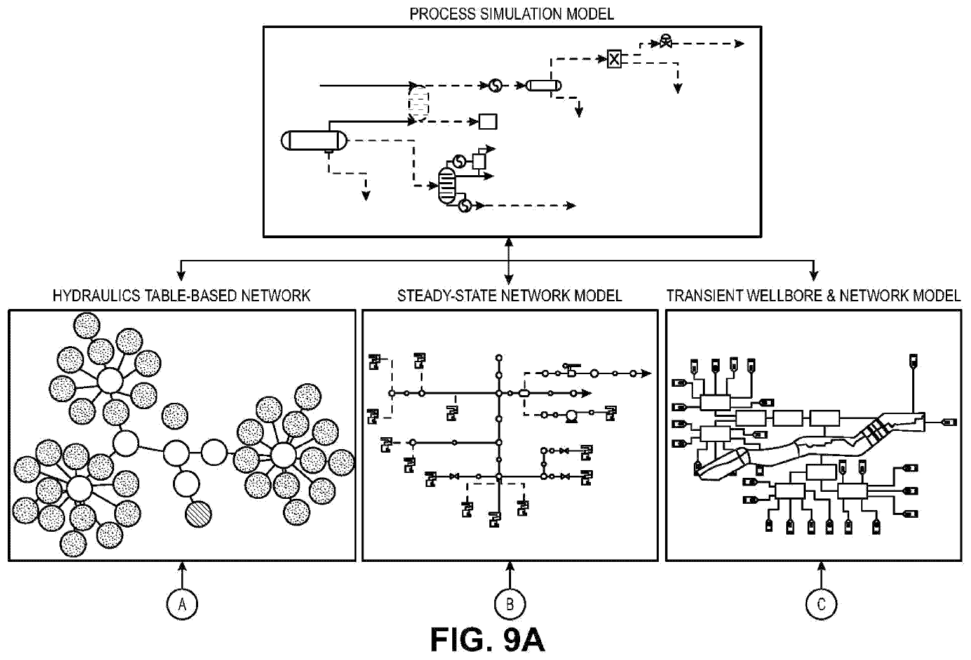

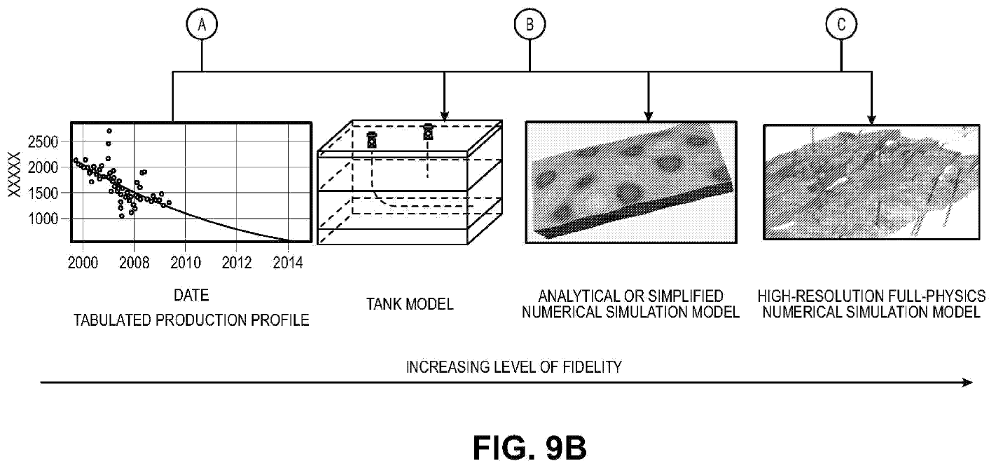

In FIGS. 4A-4C (described above), the fluid production rates can be calculated from any model capable of forecasting fluid flow from the subsurface. Depending on the fidelity for asset development planning, models ranging from tabulated profiles to high-resolution simulation models can be utilized. These include models with integrated high-resolution subsurface models and surface production models, inclusive of AI-ML models which have been trained to accurately forecast reservoir performance. FIGS. 9A and 9B illustrate a multi-fidelity model workflow for fluid production rates calculation, according to an embodiment.

### Calculation of Energy Consumption and Emissions

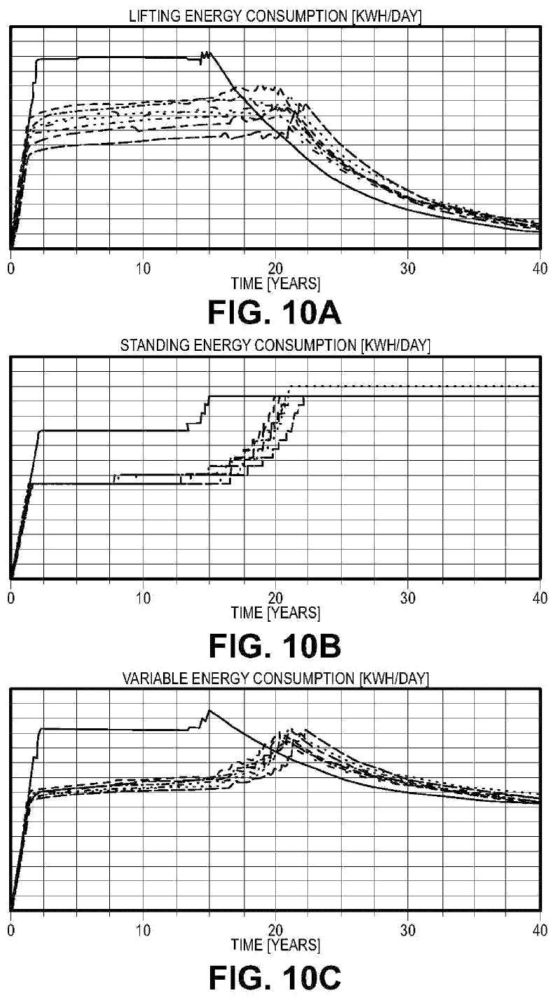

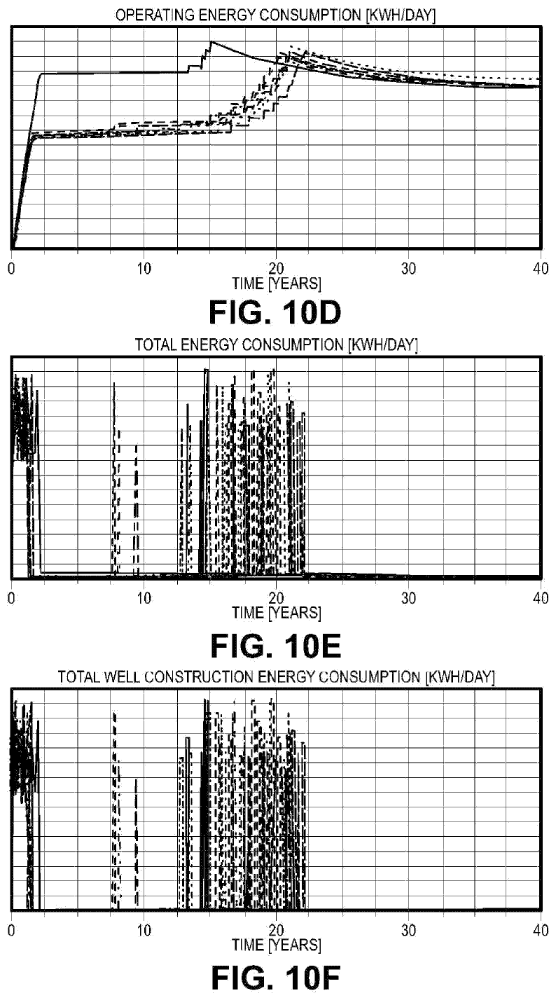

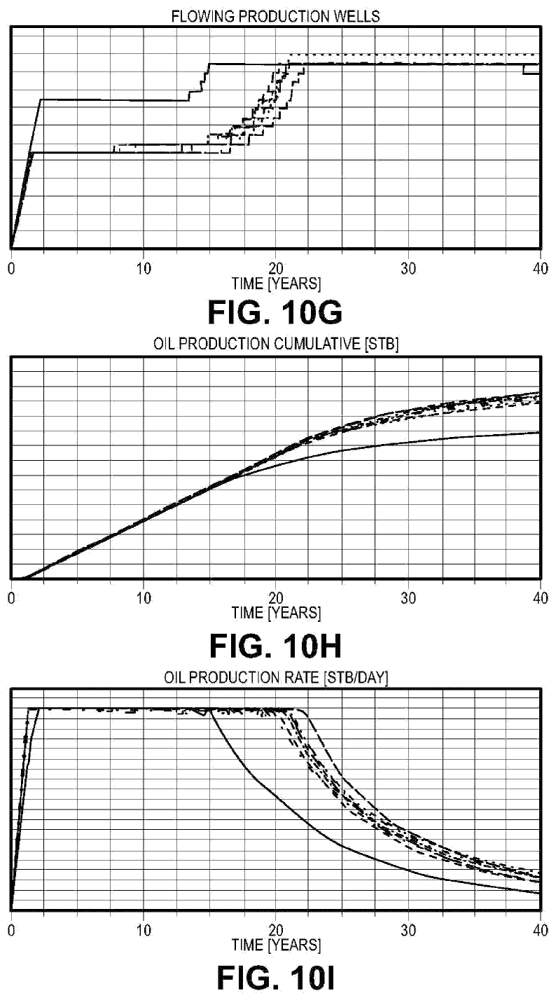

At each point in time, the set of well and production operating conditions may be known and used to calculate the incremental energy consumption for the time period. These model the different energy consumption amounts, which may include new well construction energy consumption, asset operational energy consumption, fluid lifting energy consumption, or a combination thereof. The models or tables provided at the start of the workflow may be used to calculate the energy consumption and derive related values for CO₂e (i.e., carbon dioxide equivalent) and carbon intensity. FIGS. 10A-10I illustrate a plurality of graphs that show how different development options may be evaluated to compare production alongside energy consumption metrics, according to an embodiment. More particularly, FIG. 10A shows total lifting energy consumption versus time, FIG. 10B shows standing energy consumption versus time, FIG. 10C shows variable energy consumption versus time, FIG. 10D shows operating energy consumption versus time, FIG. 10E shows total energy consumption versus time, FIG. 10F shows total well construction energy consumption versus time, FIG. 10G shows flowing production wells versus time, FIG. 10H shows oil production (cumulative) versus time, and FIG. 10I shows oil production rate versus time. The different lines in the graphs represent different (e.g., unique) digital representations and/or subsurface development plans.

### Comparison of Different Scenarios and Ranking the Scenarios

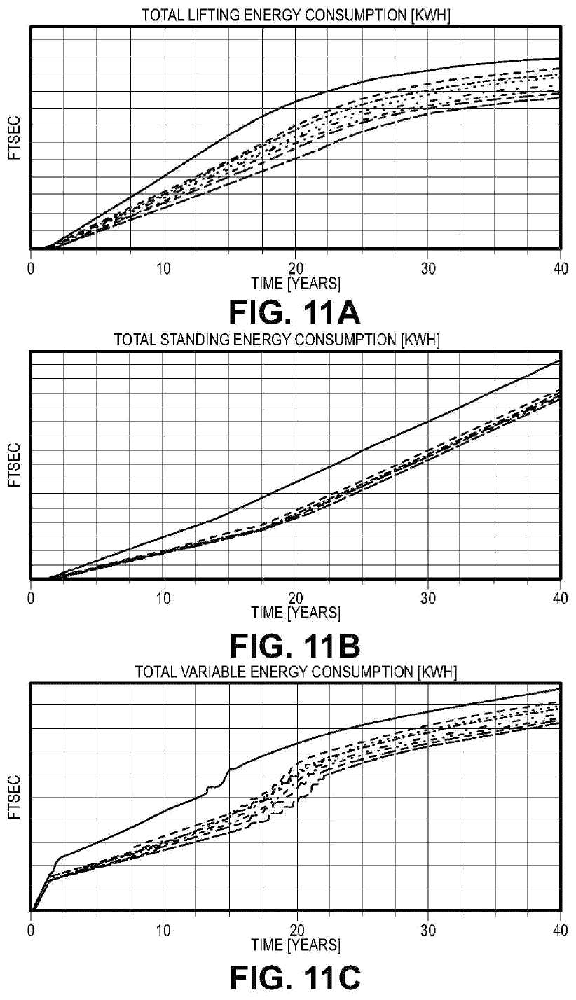

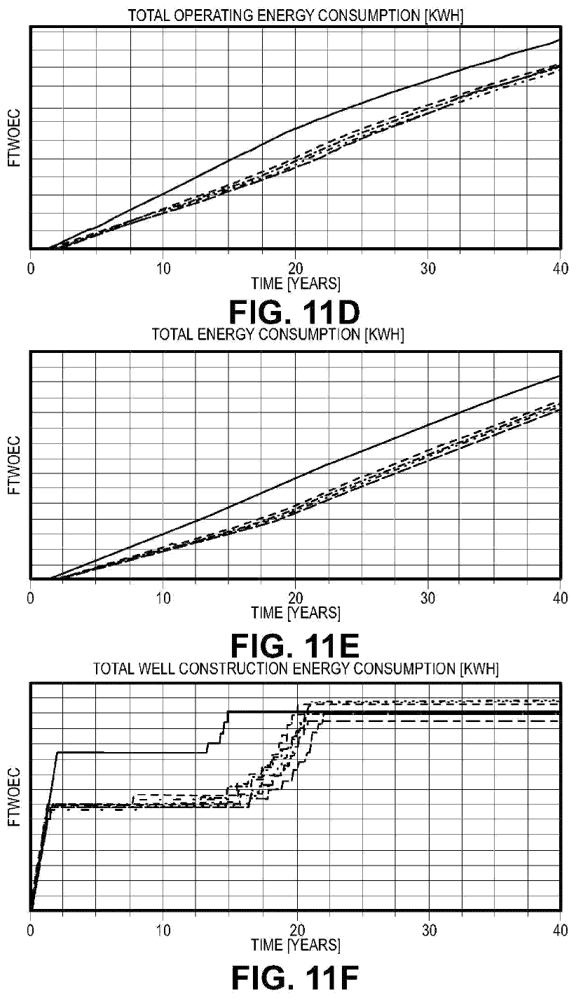

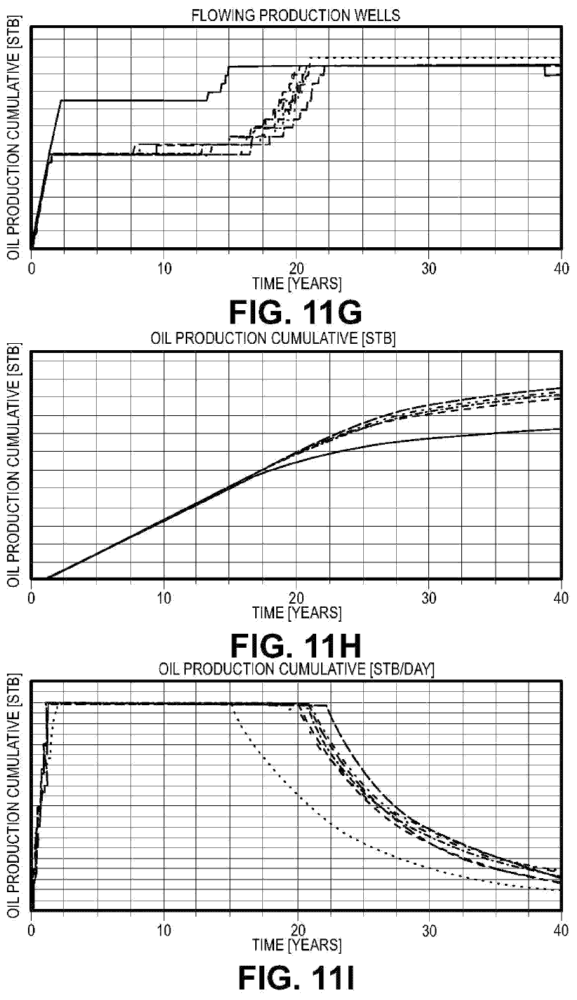

FIGS. 11A-11I illustrate a plurality of graphs that show the cumulative energy consumption from different sources for different field development scenarios, according to an embodiment. More particularly, FIG. 11A shows total lifting energy consumption versus time, FIG. 11B shows total standing energy consumption versus time, FIG. 11C shows total variable energy consumption versus time, FIG. 11D shows total operating energy consumption versus time, FIG. 11E shows total energy consumption versus time, FIG. 11F shows total well construction energy consumption versus time, FIG. 11G shows flowing production wells versus time, FIG. 11H shows oil production (cumulative) versus time, and FIG. 11I shows oil production rate versus time. The different lines in the graphs represent different (e.g., unique) digital representations and/or subsurface development plans.

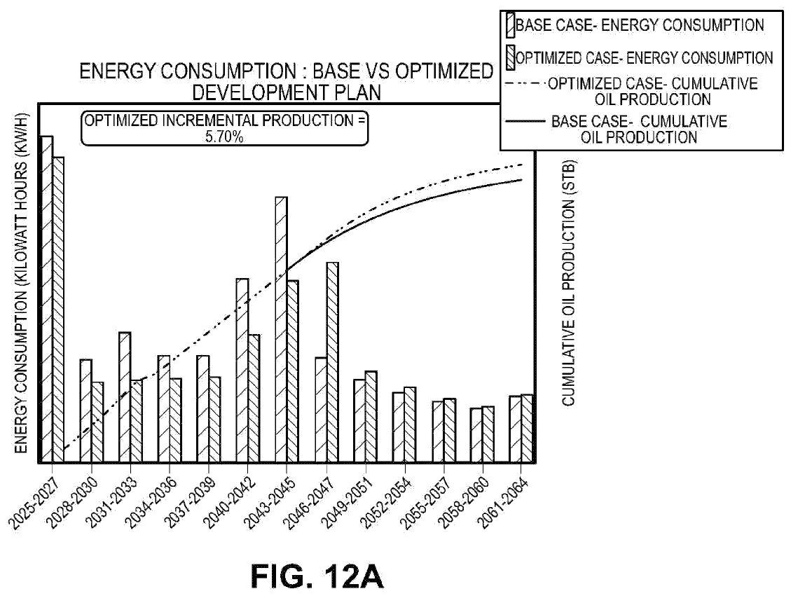

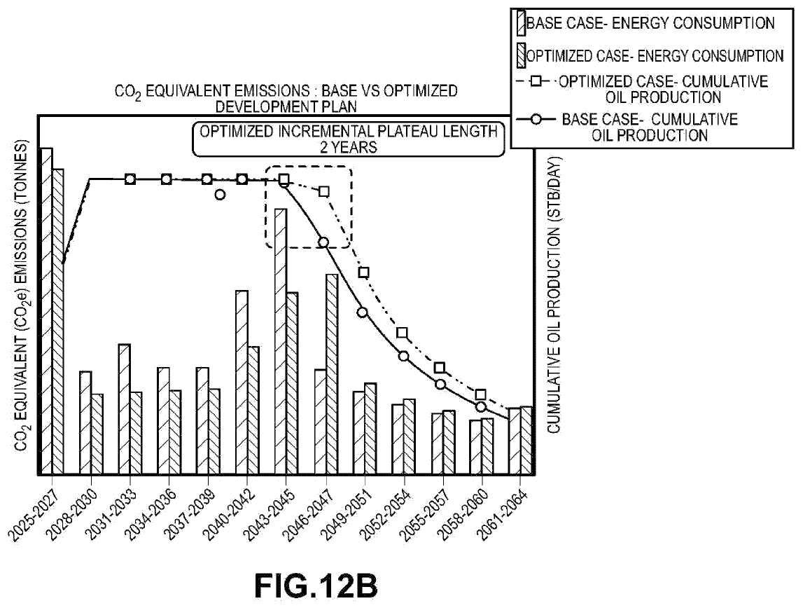

FIG. 12A illustrates a graph showing total energy consumption (e.g., 3-yearly totals), and FIG. 12B illustrates a graph showing oil production cumulative for the base and modified (e.g., optimal) field development plan, according to an embodiment. The modified (e.g., optimal) field development plan may improve the hydrocarbon recovery from the asset meeting the economic viability targets, as well as reduce the energy consumption and lead to CO₂ equivalent emissions reduction. Corresponding total CO₂e emissions (e.g., 3-yearly totals) and oil production rates for the base and optimal field development plan are also shown in FIGS. 12A and 12B.

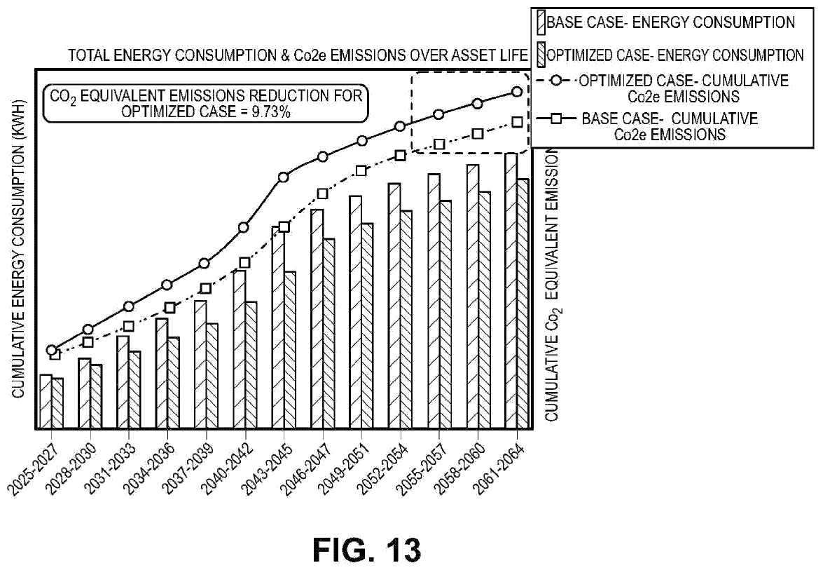

FIG. 13 illustrates a graph showing a comparison of cumulative energy consumption and CO₂ equivalent emissions, according to an embodiment. In this example, the incremental oil production for the optimal case is 5.7% compared to the base case, with evidently reduced energy consumption and reduced emissions. The modified (e.g., optimal) field development plan may achieve the dual optimization target of (1) increasing the hydrocarbon recovery (5.7% incremental oil production; 2-year extension of oil production plateau), and (2) reducing the CO₂ equivalent emissions by 9.5%.

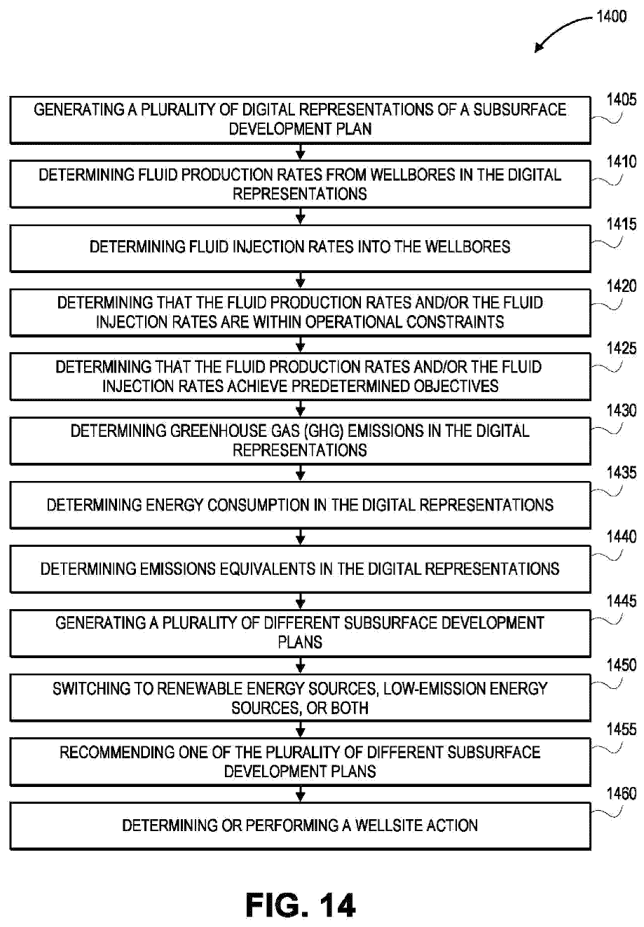

FIG. 14 illustrates a flowchart of a method 1400 for quantifying and managing energy consumption and emissions equivalents of a subsurface development plan, according to an embodiment. An illustrative order of the method 1400 is provided below; however, one or more portions of the method 1400 may be performed in a different order, combined, repeated, or omitted.

The method 1400 may include generating a plurality of digital representations of the subsurface development plan, as at 1405. The digital representations may include construction, maintenance, and/or interventions for wellbores, pipelines, equipment, or a combination thereof. The digital representations may be used to predict oil and gas production, underground gas storage, carbon sequestration, or a combination thereof.

Each digital representation may include a reservoir simulation model of a subsurface. The reservoir simulation model includes a description of an architecture of the subsurface, reservoir compartmentalization, rock and fluid properties, fluid flow characteristics, geometries of the wellbores, or a combination thereof. The reservoir simulation model may incorporate an impact of subsurface uncertainty in geological structure and rock and fluid property distributions. Each digital representation may also include a model of a wellsite infrastructure. The wellsite infrastructure may include the wellbores, the pipelines, the equipment, or a combination thereof. Each digital representation may also include a model of a surface infrastructure. The surface infrastructure may include an oil and gas processing facility, a carbon capture and compression facility, or both.

The method 1400 may also include determining fluid production rates from the wellbores, as at 1410. More particularly, this may include determining fluid production rates from the wellbores in the digital representations of the subsurface development plan.

The method 1400 may also include determining fluid injection rates into the wellbores, as at 1415. More particularly, this may include determining fluid injection rates into the wellbores in the digital representations of the subsurface development plan.

The method 1400 may also include determining that the fluid production rates and/or the fluid injection rates are within operational constraints of the wellbores, pipelines, equipment, or a combination thereof, as at 1420. The operational constraints may include minimum and/or maximum flow rates, minimum and/or maximum pressures, minimum and/or maximum temperatures, availability of resources to perform the construction, maintenance, and/or interventions, or a combination thereof.

The method 1400 may also include determining that the fluid production rates and/or the fluid injection rates achieve predetermined objectives, as at 1425. The predetermined objectives may include oil production rates, gas production rates, gas injection rates, water production rates, water injection rates, or a combination thereof.

The method 1400 may also include determining greenhouse gas (GHG) emissions in the digital representations, as at 1430. For example, this may include determining the GHG emissions from the surface infrastructure in the digital representations of the subsurface development plan.

The method 1400 may also include determining energy consumption in the digital representations, as at 1435. The energy consumption may be determined in response to determining that the fluid injection rates and/or the fluid production rates are within the operational constraints. The energy consumption may also or instead be determined in response to determining that the fluid injection rates and/or the fluid production rates achieve the predetermined objectives. The energy consumption may include energy consumption to construct the wellbores, energy consumption to operate the wellbores, energy consumption to provide fluid lifting in the wellbores, energy consumption to process and transport the produced and/or injected fluids, or a combination thereof.

The method 1400 may also include determining emissions equivalents in the digital representations, as at 1440. The emissions equivalents may correspond to the energy consumption in the digital representations of the subsurface development plan. The emissions equivalents may be different from the GHG emissions. The emissions equivalents may include emissions that are created when producing the energy consumed in the subsurface development plans (i.e., the energy consumption).

The method 1400 may also include generating a plurality of different subsurface development plans, as at 1445. The different subsurface development plans may be based upon the GHG emissions, the energy consumption, the emissions equivalents, or a combination thereof. Each subsurface development plan may be or include a multi-year plan for designing and/or building the wellsite infrastructure and/or the surface infrastructure. Each subsurface development plan may implement different fluid injection rates and/or different fluid production rates to produce different GHG emissions, different energy consumption, different emissions equivalents, or a combination thereof.

The method 1400 may also include (e.g., automatically) switching to renewable energy sources, low-emission energy sources, or both to power the wellsite infrastructure and the surface infrastructure, as at 1450. The switching may occur as the renewable energy sources, the low-emission energy sources, or both become available within the plurality of different subsurface development plans. The switching may occur in the wellsite infrastructure and/or surface infrastructure in the different subsurface development plans, or in the actual wellsite infrastructure and/or surface infrastructure (i.e., not in a plan).

The method 1400 may also include (e.g., automatically) recommending one of the plurality of different subsurface development plans, as at 1455. The plan may be recommended (e.g., selected) to decrease the GHG emissions, the energy consumption, the emissions equivalents, or a combination thereof while increasing a value related to development of the subsurface.

The method 1400 may also include determining or performing a (e.g., wellsite) action, as at 1460. The wellsite action may be determined or performed based at least partially upon the GHG emissions, the energy consumption, the emissions equivalents, the different subsurface development plans, the recommended subsurface development plan, or a combination thereof. In one embodiment, performing the wellsite action may include generating and/or transmitting a signal (e.g., using the computing system 1500) which instructs or causes a physical action to take place. In another embodiment, performing the wellsite action may include physically performing the action (e.g., either manually or automatically). Illustrative physical actions may include, but are not limited to, selecting a location to drill a wellbore, determining risks while drilling the wellbore, drilling the wellbore, varying a trajectory of the wellbore, varying a weight on the bit of a downhole tool that is drilling the wellbore, varying a composition or flow rate of a drilling fluid that is introduced into the wellbore, building/constructing the actual wellsite infrastructure and/or the actual surface infrastructure, switching actual energy sources, or a combination thereof.

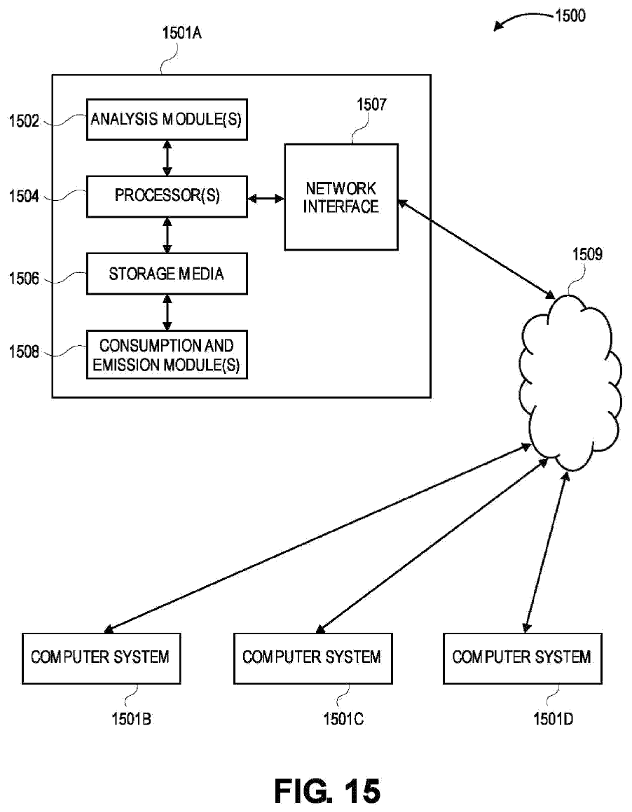

In some embodiments, any of the methods of the present disclosure may be executed by a computing system. FIG. 15 illustrates an example of such a computing system 1500, in accordance with some embodiments. The computing system 1500 may include a computer or computer system 1501A, which may be an individual computer system 1501A or an arrangement of distributed computer systems. The computer system 1501A includes one or more analysis module(s) 1502 configured to perform various tasks according to some embodiments, such as one or more methods disclosed herein. To perform these various tasks, the analysis module 1502 executes independently, or in coordination with, one or more processors 1504, which is (or are) connected to one or more storage media 1506. The processor(s) 1504 is (or are) also connected to a network interface 1507 to allow the computer system 1501A to communicate over a data network 1509 with one or more additional computer systems and/or computing systems, such as 1501B, 1501C, and/or 1501D (note that computer systems 1501B, 1501C and/or 1501D may or may not share the same architecture as computer system 1501A, and may be located in different physical locations, e.g., computer systems 1501A and 1501B may be located in a processing facility, while in communication with one or more computer systems such as 1501C and/or 1501D that are located in one or more data centers, and/or located in varying countries on different continents).

A processor can include a microprocessor, microcontroller, processor module or subsystem, programmable integrated circuit, programmable gate array, or another control or computing device.

The storage media 1506 can be implemented as one or more computer-readable or machine-readable storage media. Note that while in the example embodiment of FIG. 15 storage media 1506 is depicted as within computer system 1501A, in some embodiments, storage media 1506 may be distributed within and/or across multiple internal and/or external enclosures of computing system 1501A and/or additional computing systems. Storage media 1506 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above can be provided on one computer-readable or machine-readable storage medium, or alternatively, can be provided on multiple computer-readable or machine-readable storage media distributed in a large system having possibly plural nodes. Such computer-readable or machine-readable storage medium or media is (are) considered to be part of an article (or article of manufacture). An article or article of manufacture can refer to any manufactured single component or multiple components. The storage medium or media can be located either in the machine running the machine-readable instructions, or located at a remote site from which machine-readable instructions can be downloaded over a network for execution.

In some embodiments, computing system 1500 contains one or more consumption and/or emission module(s) 1508 that may perform at least a portion of one or more of the method(s) described above. It should be appreciated that computing system 1500 is only one example of a computing system, and that computing system 1500 may have more or fewer components than shown, may combine additional components not depicted in the example embodiment of FIG. 15, and/or computing system 1500 may have a different configuration or arrangement of the components depicted in FIG. 15. The various components shown in FIG. 15 may be implemented in hardware, software, or a combination of both hardware and software, including one or more signal processing and/or application specific integrated circuits.

Further, the steps in the processing methods described herein may be implemented by running one or more functional modules in information processing apparatus such as general purpose processors or application specific chips, such as ASICs, FPGAs, PLDs, or other appropriate devices. These modules, combinations of these modules, and/or their combination with general hardware are all included within the scope of protection of the invention.

Geologic interpretations, models and/or other interpretation aids may be refined in an iterative fashion; this concept is applicable to embodiments of the present methods discussed herein. This can include use of feedback loops executed on an algorithmic basis, such as at a computing device (e.g., computing system 1500, FIG. 15), and/or through manual control by a user who may make determinations regarding whether a given step, action, template, model, or set of curves has become sufficiently accurate for the evaluation of the subterranean three-dimensional geologic formation under consideration.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. Moreover, the order in which the elements of the methods are illustrated and described may be re-arranged, and/or two or more elements may occur simultaneously. The embodiments were chosen and described in order to best explain the principles of the invention and its practical applications, to thereby enable others skilled in the art to best utilize the invention and various embodiments with various modifications as are suited to the particular use contemplated.

1. A method for quantifying and managing energy consumption and emissions equivalents of a subsurface development plan, the method comprising:
generating a plurality of digital representations of the subsurface development plan, wherein the subsurface development plan comprises a plurality of wellbores, and wherein each digital representation comprises a reservoir simulation model of a subsurface, a model of a wellsite infrastructure, and a model of a surface infrastructure;
determining fluid production rates from the wellbores, fluid injection rates into the wellbores, or both based upon the digital representations;
determining that the fluid production rates, the fluid injection rates, or both are within operational constraints, achieve predetermined objectives, or both;
determining greenhouse gas (GHG) emissions from the surface infrastructure based upon the digital representations;
determining the energy consumption and the emissions equivalents based upon the digital representations, wherein the emissions equivalents correspond to the energy consumption; and
generating a plurality of different subsurface development plans based upon the GHG emissions, the energy consumption, the emissions equivalents, or a combination thereof, wherein each of the different subsurface development plans comprises a multi-year plan for designing and building the wellsite infrastructure and the surface infrastructure.

2. The method of claim 1, wherein the digital representations of the subsurface development plan are used to predict oil and gas production, underground gas storage, carbon sequestration, or a combination thereof.

3. The method of claim 1, wherein the digital representations of the subsurface development plan comprise construction, maintenance, or interventions for the wellbores, pipelines, equipment, or a combination thereof.

4. The method of claim 3, wherein the operational constraints pertain to the wellbores, the pipelines, the equipment, or the combination thereof.

8. The method of claim 1, wherein the energy consumption is determined in response to determining that the fluid injection rates and the fluid production rates are within the operational constraints and achieve the predetermined objectives.

9. The method of claim 1, wherein each of the different subsurface development plans implements different fluid injection rates and different fluid production rates to produce different energy consumption, and different emissions equivalents.

10. The method of claim 1, further comprising displaying the plurality of different subsurface development plans.

11. A computing system comprising:
one or more processors; and
a memory system comprising one or more non-transitory computer-readable media storing instructions that, when executed by at least one of the one or more processors, cause the computing system to perform operations, the operations comprising:
generating a plurality of digital representations of a subsurface development plan, wherein the digital representations comprise construction, maintenance, or interventions for wellbores, pipelines, equipment, or a combination thereof, wherein the digital representations are used to predict oil and gas production, underground gas storage, carbon sequestration, or a combination thereof, and wherein each digital representation comprises:
a reservoir simulation model of a subsurface;
a model of a wellsite infrastructure; and
a model of a surface infrastructure,
wherein the reservoir simulation model comprises a description of an architecture of the subsurface, reservoir compartmentalization, rock and fluid properties, fluid flow characteristics, geometries of the wellbores, or a combination thereof, wherein the reservoir simulation model incorporates an impact of subsurface uncertainty in geological structure and rock and fluid property distributions, wherein the wellsite infrastructure comprises the wellbores, the pipelines, the equipment, or a combination thereof, and wherein the surface infrastructure comprises an oil and gas processing facility, a carbon capture and compression facility, or both;
determining fluid production rates from the wellbores based upon the digital representations;
determining fluid injection rates into the wellbores based upon the digital representations;
determining that the fluid production rates and the fluid injection rates are within operational constraints of the wellbores, the pipelines, the equipment, or a combination thereof;
determining that the fluid production rates and the fluid injection rates achieve predetermined objectives;
determining greenhouse gas (GHG) emissions from the surface infrastructure;
determining energy consumption based upon the digital representations, wherein the energy consumption is determined in response to determining that the fluid injection rates and the fluid production rates are within the operational constraints and achieve the predetermined objectives;
determining emissions equivalents corresponding to the energy consumption based upon the digital representations; and
generating a plurality of different subsurface development plans based upon the GHG emissions, the energy consumption, the emissions equivalents, or a combination thereof, wherein each of the different subsurface development plans comprises a multi-year plan for designing and building the wellsite infrastructure and the surface infrastructure, and wherein each of the different subsurface development plans implements different fluid injection rates and different fluid production rates to produce different GHG emissions, different energy consumption, and different emissions equivalents.

13. The computing system of claim 11, wherein the operational constraints comprise minimum and maximum flow rates, minimum and maximum pressures, minimum and maximum temperatures, availability of resources to perform the construction, the maintenance, the interventions, or a combination thereof, and wherein the predetermined objectives comprise oil production rates, gas production rates, gas injection rates, water production rates, water injection rates, or a combination thereof.

14. The computing system of claim 11, wherein the energy consumption comprises energy consumption to construct the wellbores, energy consumption to operate the wellbores, energy consumption to provide fluid lifting in the wellbores, energy consumption to process and transport the produced and injected fluids, or a combination thereof, and wherein the emissions equivalents are different from the GHG emissions and comprise emissions that are created when producing the energy consumed in the digital representations.

16. A non-transitory computer-readable medium storing instructions that, when executed by at least one processor of a computing system, cause the computing system to perform operations, the operations comprising:
generating a plurality of digital representations of a subsurface development plan, wherein the digital representations comprise construction, maintenance, and interventions for wellbores, pipelines, equipment, or a combination thereof, wherein the digital representations are used to predict oil and gas production, underground gas storage, carbon sequestration, or a combination thereof, and wherein each digital representation comprises:
a reservoir simulation model of a subsurface, wherein the reservoir simulation model comprises a description of an architecture of the subsurface, reservoir compartmentalization, rock and fluid properties, fluid flow characteristics, geometries of the wellbores, or a combination thereof, and wherein the reservoir simulation model incorporates an impact of subsurface uncertainty in geological structure and rock and fluid property distributions;
a model of a wellsite infrastructure, wherein the wellsite infrastructure comprises the wellbores, the pipelines, the equipment, or a combination thereof; and
a model of a surface infrastructure, wherein the surface infrastructure comprises an oil and gas processing facility, a carbon capture and compression facility, or both;
determining fluid production rates from the wellbores based upon the digital representations;
determining fluid injection rates into the wellbores based upon the digital representations;
determining that the fluid production rates and the fluid injection rates are within operational constraints of the wellbores, pipelines, and equipment, wherein the operational constraints comprise minimum and maximum flow rates, minimum and maximum pressures, minimum and maximum temperatures, availability of resources to perform the construction, maintenance, and interventions, or a combination thereof;
determining that the fluid production rates and the fluid injection rates achieve predetermined objectives, wherein the predetermined objectives comprise oil production rates, gas production rates, gas injection rates, water production rates, water injection rates, or a combination thereof;
determining greenhouse gas (GHG) emissions from the surface infrastructure based upon the digital representations;
determining energy consumption based upon the digital representations, wherein the energy consumption is determined in response to determining that the fluid injection rates and the fluid production rates are within the operational constraints and achieve the predetermined objectives, wherein the energy consumption comprises energy consumption to construct the wellbores, energy consumption to operate the wellbores, energy consumption to provide fluid lifting in the wellbores, energy consumption to process and transport the produced and injected fluids, or a combination thereof;
determining emissions equivalents corresponding to the energy consumption based upon the digital representations, wherein the emissions equivalents are different from the GHG emissions and comprise emissions that are created when producing the energy consumed in the digital representations;
generating a plurality of different subsurface development plans based upon the GHG emissions, the energy consumption, the emissions equivalents, or a combination thereof, wherein each of the different subsurface development plans comprises a multi-year plan for designing and building the wellsite infrastructure and the surface infrastructure, and wherein each of the different development plan implements different fluid injection rates and different fluid production rates to produce different GHG emissions, different energy consumption, and different emissions equivalents.

17. The non-transitory computer-readable medium of claim 16, wherein the operations further comprise automatically switching to renewable energy sources, low-emission energy sources, or both to power the wellsite infrastructure and the surface infrastructure as the renewable energy sources, the low-emission energy sources, or both become available within the plurality of different subsurface development plans.

18. The non-transitory computer-readable medium of claim 16, wherein the operations further comprise automatically recommending one of the plurality of different subsurface development plans to decrease the GHG emissions, the energy consumption, the emissions equivalents, or a combination thereof while increasing a value related to development of the subsurface.

19. The non-transitory computer-readable medium of claim 16, wherein the operations further comprise displaying the digital representations, the different subsurface development plans, or both.

20. The non-transitory computer-readable medium of claim 16, wherein the operations further comprise performing a wellsite action in response to the different subsurface development plans.
